(19) United States
(12) Patent Application Publication
(10) Pub. No.: US 2026/0305490 A1
(43) Pub. Date: Oct. 1, 2026

(54) HYBRID WIRE BONDING SCHEMES FOR SEMICONDUCTOR DEVICES, INCLUDING FOR SEMICONDUCTOR DEVICES WITH INTERFACE CHIPS

(71) Applicant: Micron Technology, Inc., Boise, ID (US)

(72) Inventors: Gang Zhao, Boise, ID (US); Soham Bhattacharjee, Kolkata (IN); Chandana Rani Ravella, Bengaluru (IN); Jack E. Murray, Boise, ID (US); M Ataul Karim, Meridian, ID (US); Aparna U. Limaye, Boise, ID (US)

(21) Appl. No.: 19/577,401

(22) Filed: Mar. 25, 2026

Related U.S. Application Data
(60) Provisional application No. 63/778,901, filed on Mar. 27, 2025.

(51) Int. Cl. H10W 90/24; H10W 70/65; H10W 90/00

(52) U.S. Cl. CPC H10W 90/24; H10W 70/65; H10W 90/732; H10W 90/752; H10W 90/753; H10W 90/754

(57) ABSTRACT

Hybrid wire bonding schemes for semiconductor devices (and associated systems, devices, and methods) are disclosed herein. In one embodiment, a semiconductor device includes a substrate, an interface chip disposed on the substrate, and a plurality of semiconductor dies disposed on the substrate. The semiconductor device can further include a first plurality of wire bonds coupling a first subset of the plurality of semiconductor dies to the substrate apart from the interface chip, and a second plurality of wire bonds coupling a second subset of the plurality of semiconductor dies to the substrate via the interface chip. In some embodiments, the interface chip is coupled to the substrate via a third plurality of wire bonds and a fourth plurality of wire bonds positioned on opposite sides of the interface chip from one another.

### CROSS-REFERENCE TO RELATED APPLICATION(S)

The present application claims priority to U.S. Provisional Patent Application No. 63/778,901, filed Mar. 27, 2025, the disclosure of which is incorporated herein by reference in its entirety.

### TECHNICAL FIELD

This disclosure relates generally to semiconductor packaging. For example, several embodiments of the present technology described in detail below relate to hybrid wire bonding schemes for semiconductor devices, such as semiconductor devices that incorporate interface chips and semiconductor dies arranged in stacked configurations.

### BACKGROUND

Semiconductor devices continue to evolve to meet increasing demands for higher performance, smaller form factors, and greater functionality. As these devices become more complex, packaging technologies play a crucial role in enabling advanced functionality while maintaining or reducing overall package size. One approach to achieving higher density and performance involves stacking multiple semiconductor dies within a single package.

Stacked die configurations present challenges in terms of interconnections between the dies themselves and with external package connections. Wire bonding remains a widely used and cost-effective method for creating these interconnections. As the number of stacked dies increases and the spacing between dies decreases, however, traditional wire bonding schemes face limitations in terms of wire length, loop height, and signal integrity.

The introduction of interface chips in stacked die packages has enabled new possibilities for managing connections and enhancing overall package performance. These interface chips can serve various functions, such as signal and power routing. Integrating an interface chip into semiconductor devices that incorporate stacked die configurations, however, introduces additional complexities in terms of wire bonding arrangements and overall package design. And as the demand for higher performance and more compact semiconductor packages continues to grow, there is an ongoing need for innovative wire bonding approaches that can address these challenges.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1A illustrates a partially schematic side view of a semiconductor device.

FIG. 1B illustrates a partially schematic top view of an interface chip of the semiconductor device of FIG. 1A.

FIG. 2A illustrates a partially schematic side view of another semiconductor device.

FIG. 2B illustrates a partially schematic top view of an interface chip of the semiconductor device of FIG. 2A.

FIG. 3A illustrates a partially schematic side view of a semiconductor device configured in accordance with various embodiments of the present technology.

FIG. 3B illustrates a partially schematic top view of an interface chip of the semiconductor device of FIG. 3A, configured in accordance with various embodiments of the present technology.

FIG. 4A illustrates a partially schematic side view of another semiconductor device configured in accordance with various embodiments of the present technology.

FIG. 4B illustrates a partially schematic top view of an interface chip of the semiconductor device of FIG. 4A.

FIG. 5 illustrates a block diagram of a system including a semiconductor device, configured in accordance with various embodiments of the present technology.

FIG. 6 is a schematic showing a system that includes a semiconductor device assembly configured in accordance with various embodiments of the present technology.

### DETAILED DESCRIPTION

The present technology is generally directed to hybrid wire bonding schemes for semiconductor devices, such as semiconductor devices that employ interface chips. For example, several embodiments described herein are directed to hybrid wire bonding schemes for low-power dynamic random-access memory (LPDRAM) devices that include a stack of memory dies and an interface chip disposed on a package substrate. Such hybrid wire bonding schemes can utilize a combination of (a) wire bonds extending between the substrate and a first subset of memory dies of the stack and (b) wire bonds extending between the interface chip and a second subset of memory dies of the stack. This hybrid approach is expected to shorten signal paths, reduce power loss, and improve signal integrity in comparison to other wire bonding schemes.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc. For example, although described below primarily in the context of LPDRAM devices, the present technology is not so limited. Indeed, the present technology can be employed in other semiconductor devices that employ an interface chip with wire bonding, such as in other memory devices that include double data rate (DDR) fifth-generation (DDR5) memory dies, DDR sixth-generation (DDR6) memory dies, NAND flash memory dies, magnetic RAM (MRAM) memory dies, etc. As another example, although hybrid wire bonding schemes are primarily described below in the context of semiconductor devices that employ interface chips, the present technology can also be used in semiconductor devices that employ other types of silicon chips besides interface chips, such as data buffer chips, registered clock driver chips, re-driver chips, re-timer chips, multiplexer integrated circuit chips, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

### A. Overview

Many semiconductor devices incorporate interface chips to manage connections and enhance overall package performance. These interface chips can serve various functions, such as signal routing and power distribution. Some such semiconductor devices, however, employ wire bonding schemes where all signals (including power and ground) are first routed via wire bonds from bond fingers on a package substrate to the interface chips and then are routed via wire bonds from the interface chips to semiconductor dies of the semiconductor devices.

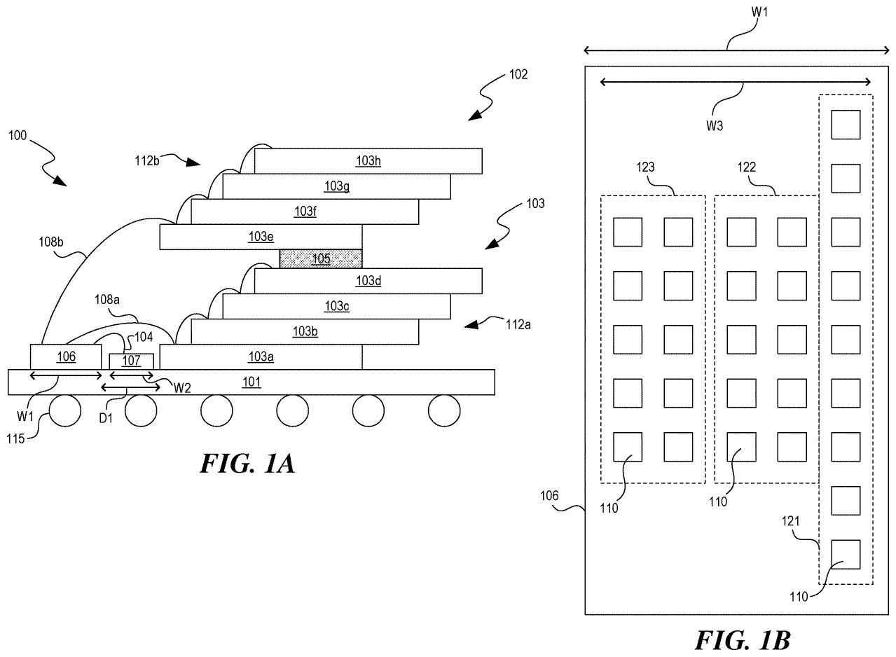

For example, consider FIG. 1A that illustrates a partially schematic side view of a semiconductor device 100. As shown, the semiconductor device 100 includes (i) a package substrate 101 having a plurality of bond fingers 107 (only one is shown in the side view of FIG. 1A) and (ii) an interface chip 106 disposed on the substrate 101. The interface chip 106 is illustrated with a width W1, and the bond finger 107 shown in FIG. 1A is illustrated with a width W2. The semiconductor device 100 further includes a stack 102 of semiconductor dies 103 (identified individually in FIG. 1A as first through eighth semiconductor dies 103a-103h) that is also disposed on the substrate 101. The semiconductor dies 103 of FIG. 1A are arranged in a 4-4 stack configuration in which a spacer 105 is disposed between a first subset 112a of the semiconductor dies 103 (the first through fourth semiconductor dies 103a-103d) and a second subset 112b of the semiconductor dies 103 (the fifth through eighth semiconductor dies 103e-103h in the stack 102). The interface chip 106 is spaced a distance D1 from an edge of the first semiconductor dies 103a. The semiconductor device 100 further includes a plurality of external contacts 115 (e.g., solder balls, pillars, etc.) for coupling the semiconductor device 100 to external devices and/or systems, such as a host device (not shown).

In the design illustrated in FIG. 1A, the interface chip 106 is coupled to the bond fingers 107 on the substrate 101 via wire bonds 104 (only one is shown in the side view of FIG. 1A). In addition, the interface chip 106 (a) is coupled to the first subset 112a of semiconductor dies 103 via a first plurality of wire bonds 108a (only one is shown in the side view of FIG. 1A) and (b) is coupled to the second subset 112b of semiconductor dies 103 via a second plurality of wire bonds 108b (only one is shown in the side view of FIG. 1A). More specifically, FIG. 1B illustrates a partially schematic top view of the interface chip 106 of the semiconductor device 100 of FIG. 1A. As shown, the interface chip 106 includes a pad ring area having a first set 121 of bond pads 110 for coupling the interface chip 106, via the wire bonds 104 of FIG. 1A, to the bond fingers 107 on the substrate 101. The pad ring area further includes a second set 122 of bond pads 110 and a third set 123 of bond pads 110 for coupling the interface chip 106, via the wire bonds 108a and 108b, respectively, to the first subset 112a of semiconductor dies 103 and the second subset 112b of semiconductor dies 103, respectively. The pad ring area is illustrated with a width W3. Various ones of the bond pads 110 in the pad ring area can be coupled to one another via a redistribution layer (not shown) formed within or on the interface chip 106.

In the illustrated design, all signals (e.g., command/address (CA) signals, chip select (CS) signals, clock (CK) signals, power, ground) transmitted from the substrate 101 to one or more of the semiconductor dies 103 are first routed to the interface chip 106 via the wire bonds 104. In turn, these signals are routed to corresponding semiconductor dies 103 of the stack 102. Stated another way, in this design, each of the signals transmitted between the substrate 101 and one or more semiconductor dies 103 of the stack 102 is routed through the interface chip 106.

Such a wire bonding scheme can lead to several drawbacks. For example, because signals are first routed through the interface chip 106 in the design illustrated in FIG. 1A, signal paths extending between the bond fingers 107 on the substrate 101 and the semiconductor dies 103 are relatively long in comparison to signal paths that extend directly from the substrate to the semiconductor dies 103. It is expected that these longer signal paths contribute at least in part to voltage (IR) drops observed on power and ground wire bonds utilized in the design of FIG. 1A. In addition, because all signals transmitted to the semiconductor dies 103 are first routed through the interface chip 106, the pad ring area (illustrated in FIG. 1B) of the interface chip 106 includes multiple sets 122, 123 of bond pads 110 to accommodate multiple rows of wire bonds 108a, 108b that extend between the interface chip 106 and the semiconductor dies 103 in the stack 102. As a result, several of the bond pads 110 in the sets 122, 123 of the pad ring area are spaced large distances from edges of the interface chip 106, contributing to longer signal paths, longer redistribution layer lengths, longer wire bond lengths, increased pad capacitance in the interface chip 106, and/or degraded performance.

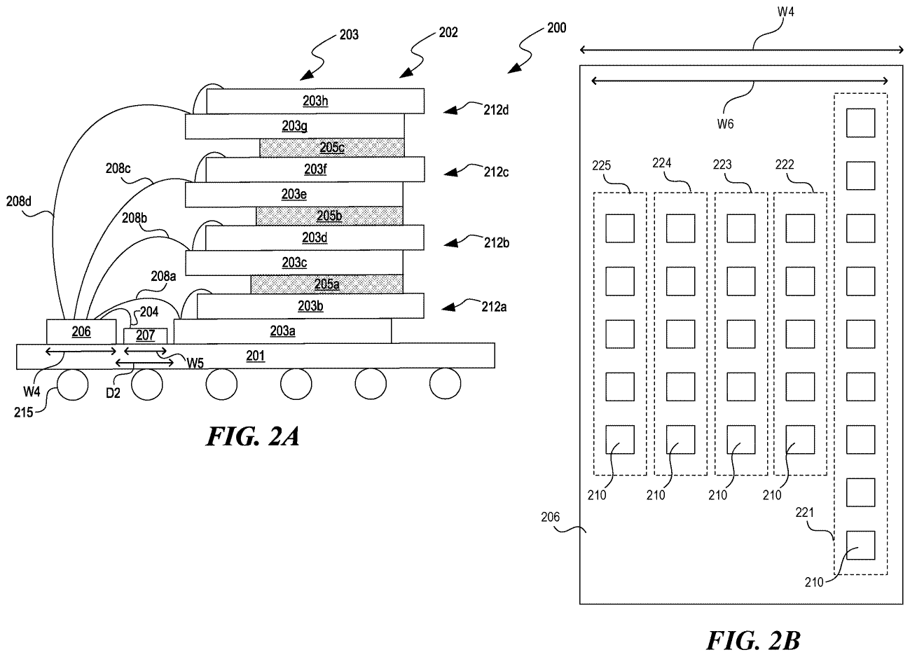

Other wire bonding schemes suffer from similar and other drawbacks. For example, consider FIG. 2A that illustrates a partially schematic side view of another semiconductor device 200. As shown, the semiconductor device 200 includes (i) a package substrate 201 having a plurality of bond fingers 207 (only one is shown in the side view of FIG. 2A) and (ii) an interface chip 206 disposed on the substrate 201. The interface chip 206 is illustrated with a width W4, and the bond finger 207 shown in FIG. 2A is illustrated with a width W5. The semiconductor device 200 further includes a stack 202 of semiconductor dies 203 (identified individually in FIG. 2A as first through eighth semiconductor dies 203a-203h) that is also disposed on the substrate 201. The semiconductor dies 203 of FIG. 2A are arranged in a 2-2-2-2 stack configuration in which (a) a first spacer 205a is disposed between a first subset 212a of the semiconductor dies 203 (the first and second semiconductor dies 203a and 203b) and a second subset 212b of the semiconductor dies 203 (the third and fourth semiconductor dies 203c and 203d), (b) a second spacer 205b is disposed between the second subset 212b of the semiconductor dies 203 and a third subset 212c of the semiconductor dies 203 (the fifth and sixth semiconductor dies 203e and 203f), and (c) a third spacer 205c is disposed between the third subset 212c of the semiconductor dies 203 and a fourth subset 212d of the semiconductor dies 203 (the seventh and eighth semiconductor dies 203g and 203h). The first through fourth subsets 212a-212d of semiconductor dies 203 are vertically aligned with one another in the stack 202. The interface chip 206 is spaced a distance D2 from an edge of the first semiconductor die 203a. The semiconductor device 200 further includes a plurality of external contacts 215 (e.g., solder balls, pillars, etc.) for coupling the semiconductor device 200 to external devices and/or systems, such as a host device (not shown).

Similar to the design illustrated in FIG. 1A, all signals transmitted between the substrate 201 and the semiconductor dies 203 of the stack 202 are routed through the interface chip 206. More specifically, the interface chip 206 is coupled to the bond fingers 207 on the substrate 201 via wire bonds 204 (only one is shown in the side view of FIG. 2A). In addition, the interface chip 206 (a) is coupled to the first subset 212a of semiconductor dies 203 via a first plurality of wire bonds 208a (only one is shown in the side view of FIG. 2A), (b) is coupled to the second subset 212b of semiconductor dies 203 via a second plurality of wire bonds 208b (only one is shown in the side view of FIG. 2A), (c) is coupled to the third subset 212c of semiconductor dies 203 via a third plurality of wire bonds 208c (only one is shown in the side view of FIG. 2A), and (d) is coupled to the fourth subset 212d of semiconductor dies 203 via a fourth plurality of wire bonds 208d (only one is shown in the side view of FIG. 2A).

FIG. 2B illustrates a partially schematic top view of the interface chip 206 of the semiconductor device 200 of FIG. 2A. As shown, the interface chip 206 can be similar to the interface chip 106 of FIG. 1B. For example, like interface chip 106, the interface chip 206 includes a pad ring area that has a first set 221 of bond pads 210 for coupling the interface chip 206, via the wire bonds 204 of FIG. 2A, to the bond fingers 207 on the substrate 201. Unlike interface chip 106, however, the pad ring area of interface chip 206 includes a second, third, fourth, and fifth set (222, 223, 224, and 225, respectively) of bond pads 210 for coupling the interface chip 206, via the wire bonds 208a, 208b, 208c, and 208d, respectively, to the first subset 212a of semiconductor dies 203, the second subset 212b of semiconductor dies 203, the third subset 212c of semiconductor dies 203, and the fourth subset 212d of semiconductor dies 203, respectively, shown in FIG. 2A. The pad ring area is illustrated with a width W6. Various ones of the bond pads 210 in the pad ring area can be coupled to one another via a redistribution layer (not shown) formed within or on the interface chip 206.

The design illustrated in FIGS. 2A and 2B suffers from several of the same drawbacks (e.g., long signal paths, voltage (IR) drop on power and ground wire bonds, and/or bond pads of a pad ring area of the interface chip 206 being spaced a greater distance from the edge of the interface chip 206 leading to longer redistribution layer lengths, increased pad capacitance, and/or degraded performance) as the design described above with reference to FIGS. 1A and 1B. In addition, the design illustrated in FIGS. 2A and 2B can also be prone to crosstalk between the wire bonds 208a-208d given the proximity of the wire bonds 208a-208d to one another, which can lead to degraded signal integrity.

To address at least some of the drawbacks discussed above, the inventors have developed hybrid wire bonding schemes for semiconductor devices, such as semiconductor devices that employ interface chips or other similar chips. For example, various embodiments described herein are directed to hybrid wire bonding schemes for semiconductor devices that include a stack of semiconductor dies and an interface chip disposed on a package substrate. Such hybrid wire bonding schemes can utilize a combination of (a) wire bonds that extend directly between the substrate and a first subset of semiconductor dies of the stack and (b) wire bonds that extend between the interface chip and a second subset of semiconductor dies of the stack. As a result, using the hybrid wire bonding schemes of the present technology, only a subset of signals transmitted between the substrate and semiconductor dies of the stack are routed through the interface chip; other signals can be routed directly between the substrate and semiconductor dies of the stack.

Hybrid wire bonding schemes of the present technology are expected to offer several advantages in comparison to the designs described above with reference to FIGS. 1A-2B. For example, because some wire bonds extend directly between a substrate and semiconductor dies of a stack, signal paths that traverse these wire bonds are shorter in comparison to signal paths that are routed through the interface chip. The shorter signal paths are expected to reduce voltage (IR) drop observed along these wire bonds and/or improve signal integrity.

As another example, hybrid wire bonding schemes of the present technology enable a smaller number of signals being routed through the interface chip. This is expected to reduce an amount of current that passes from the substrate to the interface chip, which is expected to reduce voltage (IR) drop observed on power and/or ground wire bonds of the semiconductor device. In addition, the smaller number of signals being routed through an interface chip can improve spacing between the wire bonds, which is expected to reduce the risk of crosstalk between the wire bonds and/or improve signal integrity.

As still another example, reducing the number of wire bonds that extend up from the substrate between the interface chip and the semiconductor dies can enable a re-design of the interface chip (in comparison to the interface chips 106 and 206 described above) to have an increased aspect ratio that (a) accommodates a smaller number of bond pads and/or wire bond connections and/or (b) employs shorter redistribution layer path lengths in the pad ring area of the interface chip. In turn, the interface chip can be positioned a farther distance away from edges of the semiconductor dies and/or a distance between bond pads of a pad ring area of the interface chip and edges of the interface chip can be reduced (which is expected to reduce signal path lengths, reduce pad capacitance in the interface chip, and/or improve performance). Stated another way, hybrid wire bonding schemes of the present technology can enable use of a smaller number of bond pads in the pad ring area of an interface chip, allowing for a more compact design with reduced pad capacitance and improved performance.

As yet another example, the increased aspect ratio of the interface chip can enable use of additional bond fingers on the substrate that can be coupled to the interface chip via power or ground bond wires, which is expected to improve power delivery performance. Moreover, in at least some embodiments, the smaller aspect ratio of the interface chip and/or the reduced number of wire bonds that extend between the interface chip and the semiconductor dies can enable a greater stagger of the semiconductor dies in the stack, which is expected to enable use of shorter wire bonds between (a) semiconductor dies of the stack and the interface chip and/or (b) semiconductor dies of the stack and bond fingers of the substrate, thereby shortening signal paths and improving performance of the semiconductor device.

### B. Selected Embodiments of Hybrid Wire Bonding Schemes for Semiconductor Devices with Interface Chips, and Associated Systems, Devices, and Methods

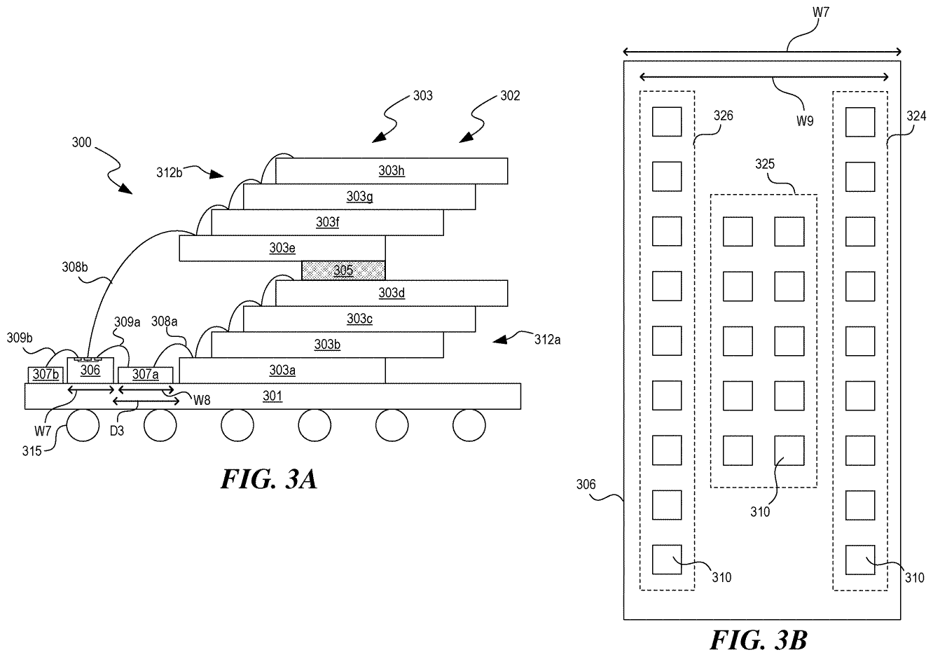

FIG. 3A illustrates a partially schematic side view of a semiconductor device 300 configured in accordance with various embodiments of the present technology. The semiconductor device 300 includes (i) a package substrate 301 having a first plurality of bond fingers 307a (only one is shown in the side view of FIG. 3A) and a second plurality of bond fingers 307b (only one is shown in the side view of FIG. 3A), (ii) an interface chip 306 disposed on the substrate 301, and (iii) a plurality of external contacts 315 (e.g., solder balls, pillars, etc.) for coupling the semiconductor device 300 to external devices and/or systems, such as a host device (not shown).

In the illustrated embodiment, the semiconductor device 300 further includes a stack 302 of semiconductor dies 303 (identified individually in FIG. 3A as first through eighth semiconductor dies 303a-303h) disposed on the substrate 301. The semiconductor dies 303a-303h of FIG. 3A are arranged in a 4-4 stack configuration in which a spacer 305 is disposed between a first subset 312a of the semiconductor dies 303 (the first through fourth semiconductor dies 303a-303d) and a second subset 312b of the semiconductor dies 303 (the fifth through eighth semiconductor dies 303e-303h in the stack 302). In some embodiments, the semiconductor device 300 can be a memory device. In these and other embodiments, one or more of the semiconductor dies 303 can be memory dies, such as LPDRAM dies or one or more other suitable types of memory dies.

In the design illustrated in FIG. 3A, the first subset 312a of the semiconductor dies 303 is coupled to the first plurality of bond fingers 307a on the substrate 301 via a first plurality of wire bonds 308a (only one is shown in the side view of FIG. 3A). For example, in contrast to the wire bonding scheme described above with reference to FIGS. 1A and 1B, the first subset 312a of the semiconductor dies 303 can be coupled directly to the first plurality of bond fingers 307a via the first plurality of wire bonds 308a. Additionally, or alternatively, the first subset 312a of the semiconductor dies 303 can be coupled to the first plurality of bond fingers 307a apart from the interface chip 306 such that signals transmitted between the substrate 301 and the first subset 312a do not pass through the interface chip 306.

The second subset 312b of semiconductor dies 303, on the other hand, is coupled to the interface chip 306 via a second plurality of wire bonds 308b (only one is shown in the side view of FIG. 3A). More specifically, the interface chip 306 is coupled to the first plurality of bond fingers 307a on the substrate 301 via wire bonds 309a (only one is shown in the side view of FIG. 3A). In turn, the signals transmitted between the substrate 301 and the interface chip 306 via the first plurality of bond fingers 307a and the wire bonds 309a can be distributed to one or more of the semiconductor dies 303e-303h of the second subset 312b via the second plurality of wire bonds 308b. In some embodiments, signals received at the interface chip 306 via one or more of the wire bonds 309a can be distributed to the semiconductor dies 303a-303h using a redistribution layer included in the interface chip 306 that couples (i) one or more bond pads of the interface chip 306 that correspond to one or more of the wire bonds 309a to (ii) one or more bond pads of the interface chip 306 that correspond to one or more of the wire bonds 308b. Thus, signals transmitted between the substrate 301 and the second subset 312b of semiconductor dies 303 can be routed and/or pass through the interface chip 306. Stated another way, in the illustrated design, some (but not all) signals can be transmitted (using the wire bonds 309a and 308b) between the substrate 301 and the semiconductor dies 303 of the stack 302 through the interface chip 306, while other signals can be transmitted (using the wire bonds 308a) between the substrate 301 and the semiconductor dies 303 of the stack 302 apart from the interface chip 306 and without passing through the interface chip 306. As a result, in comparison to the design described above with reference to FIGS. 1A and 1B, the hybrid wire bonding scheme illustrated in FIG. 3A reduces the number of signals that are routed through the interface chip 306.

Various signals can be transmitted along the wire bonds 309a, 308a, and/or 308b illustrated in FIG. 3A. For example, a first subset of the wire bonds 309a, 308a, and/or 308b can be configured as power or ground wire bonds that are configured to supply power (e.g., VDDQ, VDDQ2, VDD2, VCCP) or ground (e.g., VSS), respectively, to the interface chip 306, the first subset 312a of the semiconductor dies 303, and/or the second subset 312b of the semiconductor dies. In these and other embodiments, a second subset of the wire bonds 309a, 308a, and/or 308b can be configured to transmit control and/or clock signals (e.g., command/address (CA) signals, chip select (CS) signals, clock (CK) signals, etc.) between (a) the substrate 301 and the first subset 312a of the semiconductor dies 303, (b) the substrate 301 and the interface chip 306, and/or (c) the interface chip 306 and the second subset 312b of the semiconductor dies 303. Further, in some embodiments, the second plurality of bond fingers 307b can facilitate use of additional power and/or ground wire bonds 309b extending between the substrate 301 and the interface chip 306, which is expected to improve power delivery and/or grounding performance to the interface chip 306 and/or to the semiconductor dies 303e-303h of the second subset 312b.

Reducing the number of signals being routed through the interface chip 306 is expected to offer several advantages. For example, reducing the number of signals being routed through the interface chip 306 is expected to reduce (e.g., by approximately 50%) an amount of current that passes through the interface chip 306, which is expected to reduce voltage (IR) drop observed on power and/or ground wire bonds 308a, 308b, and/or 309a of the semiconductor device 300. In addition, as shown in FIG. 3A, the smaller number of signals being routed through the interface chip 306 can enable an increased amount of spacing between the wire bonds 308a, 308b, and/or 309a, which is expected to reduce the risk of crosstalk between these wire bonds 308a, 308b, and/or 309a and/or improve signal integrity. Furthermore, in comparison to routing signals through the interface chip 306, routing signals directly between the bond fingers 307a and the semiconductor dies 303a-303d of the first subset 312a is expected to shorten associated signal paths, thereby reducing the amount of voltage (IR) drop observed on power and ground wire bonds 308a and/or improving signal integrity of signals transmitted via the wire bonds 308a.

As another example, reducing the number of signals that are routed through the interface chip 306 can reduce a size of a pad ring area of the interface chip 306, the number of bond pads within the pad ring area, and/or one or more dimensions of the interface chip 306. More specifically, FIG. 3B illustrates a partially schematic top view of the interface chip 306 of the semiconductor device 300 of FIG. 3A. As shown, the interface chip 306 includes a pad ring area having a first set 324 of bond pads 310 for coupling the interface chip 306 (via the wire bonds 309a of FIG. 3A) to the first plurality of bond fingers 307a on the substrate 301. The pad ring area further includes a second set 325 of bond pads 310 for coupling the interface chip 306 (via the second plurality of wire bonds 308b), to the second subset 312b of semiconductor dies 303. Finally, the pad ring area can include a third set 326 of bond pads 310 for coupling the interface chip 306 (via the power and/or ground wire bonds 309b of FIG. 3A) to the second plurality of bond fingers 307b on the substrate 301.

In comparison to the pad ring area of the interface chip 106 described above with reference to FIG. 1B, the pad ring area of the interface chip 306 of FIG. 3B can include a smaller number of bond pads 310 because signals transmitted between the substrate 301 and the first subset 312a of the semiconductor dies 303 are not routed through the interface chip 306. Stated another way, the pad ring area of the interface chip 306 can omit a fourth set of bond pads that are usable to couple the interface chip 306 to the first subset 312a of the semiconductor dies 303. As a result, an aspect ratio (e.g., length to width) of the interface chip 306 can be increased in comparison to the aspect ratio of the interface chip 106 of FIGS. 1A and 1B described above. For example, the pad ring area of the interface chip 306 can have a width W9 that is smaller than the width W3 (FIG. 1B) of the pad ring area of the interface chip 106 of FIGS. 1A and 1B. In turn, the interface chip 306 can have a width W7 that is smaller than the width W1 (FIGS. 1A and 1B) of the interface chip 106 of FIGS. 1A and 1B. In some embodiments, a length of the interface chip 306 (e.g., measured in a direction extending generally perpendicular to the width W7) can be similar to a length of the interface chip 106.

The reduced number of bond pads in the pad ring area of the interface chip 306, the increased aspect ratio (e.g., the reduced width W7) of the interface chip 306, and/or the reduced width W9 of the pad ring area of the interface chip 306 are expected to offer several advantages. For example, the reduction in the number of bond pads 310 included in the pad ring area and/or the reduced width W9 of the pad ring area of the interface chip 306 are expected to shorten redistribution layer (RDL) paths coupling two or more of the bond pads 310 to one another within the interface chip 306. In turn, the shortened RDL paths are expected to (i) reduce parasitic loading and/or pad capacitance in the interface chip 306 and/or (ii) improve performance and/or signal integrity. As another example, the reduced width W9 of the pad ring area of the interface chip 306 and/or the increased aspect ratio of the interface chip 306 are expected to enable optimizing an amount of spacing between the interface chip 306 and the first semiconductor die 303a of the stack 302. As a specific example, the interface chip 306 can be positioned a distance D3 (FIG. 3A) away from an edge of the first semiconductor die 303a of the stack 302, which can be greater (e.g., by approximately 0.5 mm in some embodiments) than the distance D1 that the interface chip 106 is positioned away from an edge of the first semiconductor die 102a in FIG. 1A. The larger distance D3 can also contribute to the increased spacing between the wire bonds 308a and the wire bonds 308b, which can reduce the risk of crosstalk between the wire bonds 308a and 308b.

As still another example, given a fixed amount of space on the substrate 301 within which to arrange components of the semiconductor device 300, the increased aspect ratio (e.g., the reduced width W7) of the interface chip 306 can enable use of longer or larger bond fingers 307 on the substrate 301. As a specific example, the reduced width W7 of the interface chip 306 can facilitate using bond fingers 307a having widths W8 (FIG. 3A) that are larger than widths W2 of the bond fingers 107 of FIG. 1A. Additionally, or alternatively, given a fixed amount of space on the substrate 301 within which to arrange components of the semiconductor device 300, the increased aspect ratio of the interface chip 306 can facilitate using additional bond fingers 307 on the substrate 301, such as the bond fingers 307b shown (i) positioned on an opposite side of the interface chip 306 from the bond fingers 307a and (ii) coupled to the interface chip 306 via the wire bonds 309b. In some embodiments, use of the additional bond fingers 307b can facilitate use of additional power and/or ground wire bonds 309b extending between the substrate 301 and the interface chip 306, which is expected to improve power delivery and/or grounding performance to the interface chip 306 and/or to the semiconductor dies 303e-303h of the second subset 312b.

Although the semiconductor device 300 is illustrated in FIG. 3A with eight semiconductor dies arranged in a 4-4 stack configuration, the present technology is not so limited. In other embodiments of the present technology, semiconductor devices can include a different number of semiconductor dies (e.g., one, two, three, four, five, six, seven, or more than eight semiconductor dies) and/or can include semiconductor dies arranged in other stack configurations (e.g., 2-2-2-2 stacks, 1-1-1-1 stacks, 2-2 stacks, 4-high stacks, 8-high stacks, 16-high stacks, 32-high stacks etc.) besides a 4-4 stack configuration.

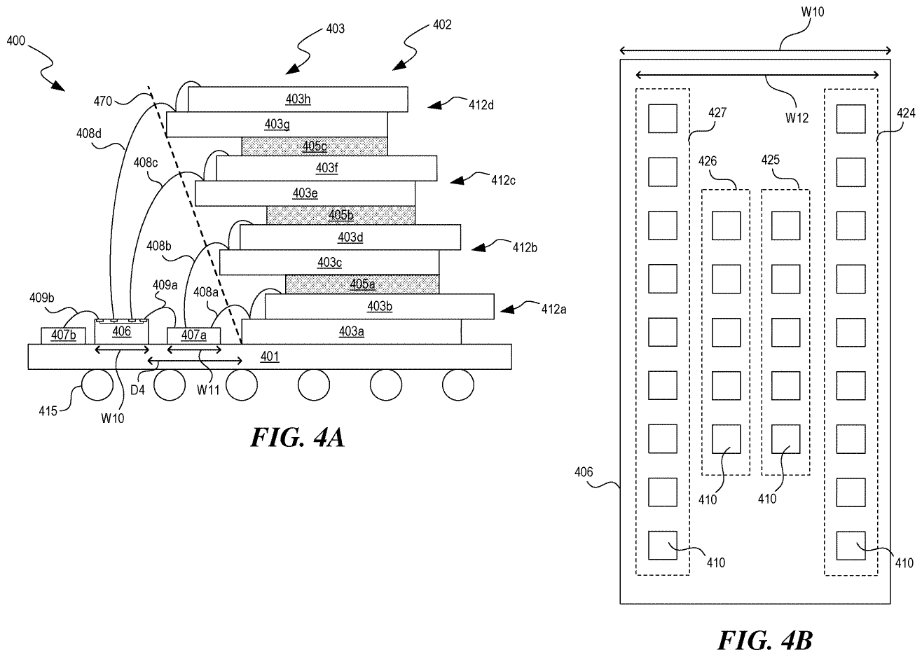

FIG. 4A illustrates a partially schematic side view of another semiconductor device 400 configured in accordance with various embodiments of the present technology. The semiconductor device 400 can be generally similar to the semiconductor device 300 described above with reference to FIGS. 3A and 3B. Thus, similar reference numbers are used across FIGS. 3A-4B to denote identical or at least generally similar components, and a detailed description of several similar aspects of the semiconductor device 400 of FIG. 4A is largely omitted here for the sake of brevity in light of the detailed description of the semiconductor device 300 provided above with reference to FIGS. 3A and 3B.

Similar to the semiconductor device 300 described above, the semiconductor device 400 of FIG. 4A includes (i) a package substrate 401 having a first plurality of bond fingers 407a (only one is shown in the side view of FIG. 4A) and a second plurality of bond fingers 407b (only one is shown in the side view of FIG. 4A), (ii) an interface chip 406 disposed on the substrate 401, and (iii) a plurality of external contacts 415 (e.g., solder balls, pillars, etc.) for coupling the semiconductor device 400 to external devices and/or systems, such as a host device (not shown). The semiconductor device 400 further includes a stack 402 of semiconductor dies 403 (identified individually in FIG. 4A as first through eighth semiconductor dies 403a-403h) that is also disposed on the substrate 401. In some embodiments, the semiconductor device 400 can be a memory device, and/or one or more of the semiconductor dies 403a-403h can be memory dies (e.g., LPDRAM dies or one or more other suitable types of memory dies).

Unlike the semiconductor dies 303 of the semiconductor device 300 described above, the semiconductor dies 403 of the semiconductor device 400 of FIG. 4A are arranged in a 2-2-2-2 stack configuration in which (a) a first spacer 405a is disposed between a first subset 412a of the semiconductor dies 403 (the first and second semiconductor dies 403a and 403b) and a second subset 412b of the semiconductor dies 403 (the third and fourth semiconductor dies 403c and 403d), (b) a second spacer 405b is disposed between the second subset 412b of the semiconductor dies 403 and a third subset 412c of the semiconductor dies 403 (the fifth and sixth semiconductor dies 403e and 403f), and (c) a third spacer 405c is disposed between the third subset 412c of the semiconductor dies 403 and a fourth subset 412d of the semiconductor dies 403 (the seventh and eighth semiconductor dies 403g and 403h). In this configuration, the first and second subsets 412a and 412b of the semiconductor dies 403 can be coupled to the first plurality of bond fingers 407a on the substrate 401 via first and second pluralities of wire bonds 408a and 408b (only one wire bond 408a and only one wire bond 408b are shown in the side view of FIG. 4A), respectively. In addition, the third and fourth subsets 412c and 412d of the semiconductor dies 403 can be coupled to the interface chip 406 via third and fourth pluralities of wire bonds 408c and 408d (only one wire bond 408c and only one wire bond 408d are shown in the side view of FIG. 4A), respectively. In particular, the interface chip 406 can be coupled to the first plurality of bond fingers 407a on the substrate 401 via wire bonds 409a (only one is shown in the side view of FIG. 4A). In turn, the signals transmitted between the substrate 401 and the interface chip 406 via the first plurality of bond fingers 407a and the wire bonds 409a can be distributed (e.g., via an RDL of the interface chip 406) to one or more of the semiconductor dies 403e-403h of the third and fourth subsets 412c and/or 412d via the third and/or fourth pluralities of wire bonds 408c and/or 408d. In other words, signals transmitted between the substrate 401 and the third and fourth subsets 412c and 412d of the semiconductor dies 403 can be routed and/or passed through the interface chip 406.

FIG. 4B illustrates a partially schematic top view of the interface chip 406 of the semiconductor device 400 of FIG. 4A. As shown, the interface chip 406 includes a pad ring area having a first set 424 of bond pads 410 for coupling the interface chip 406 (via the wire bonds 409a of FIG. 4A) to the first plurality of bond fingers 407a on the substrate 401. The pad ring area further includes a second set 425 and third set 426 of bond pads 410 for coupling the interface chip 406 (via the third plurality of wire bonds 408c and the fourth plurality of wire bonds 408d of FIG. 4A) to the third and fourth subsets 412c and 412d of the semiconductor dies 403. In addition, the pad ring area can include a third set 427 of bond pads 410 for coupling the interface chip 406 (via the power and/or ground wire bonds 409b of FIG. 4A) to the second plurality of bond fingers 407b on the substrate 401.

In comparison to the wire bonding scheme described above with reference to FIGS. 2A and 2B, the hybrid wire bonding scheme illustrated in FIGS. 4A and 4B can offer several advantages generally similar to the advantages described above with reference to the hybrid wire bonding scheme illustrated in FIGS. 3A and 3B. For example, in the embodiment illustrated in FIG. 4A, some (but not all) signals can be transmitted (using the wire bonds 409a, 408c, and 408d) between the substrate 401 and the semiconductor dies 403 of the stack 402 through the interface chip 406, while other signals can be transmitted (using the wire bonds 408a and 408b) between the substrate 401 and the semiconductor dies 403 of the stack 402 apart from the interface chip 406 and without passing through the interface chip 406. As a result, in comparison to the design described above with reference to FIG. 2A, the hybrid wire bonding scheme illustrated in FIG. 4A can reduce the number of signals that are routed through the interface chip 406. In turn, the amount of current that passes through the interface chip 406 can be reduced, which is expected to reduce voltage (IR) drop observed on power and/or ground wire bonds 408a, 408b, 408c, 408d, and/or 409a of the semiconductor device 400. In addition, spacing between the wire bonds 408a, 408b, 408c, 408d, and/or 409a can be increased in comparison to the arrangement of the wire bonds 208a, 208b, 208c, 208d, and/or 209 in FIG. 2A, which is expected to reduce the risk of crosstalk between the wire bonds 408a, 408b, 408c, 408d, 409a, and/or 409b and/or improve signal integrity. Furthermore, coupling the semiconductor dies 403a-403d to the bond fingers 407a via the wire bonds 408a and/or 408b without passing through the interface chip 406 is expected to enable use of (i) shorter wire bonds 408a and/or 408b and/or (ii) shorter signal paths, reducing voltage (IR) drop observed on power and ground wire bonds 408a and/or 408b and/or improving signal integrity.

Additionally, or alternatively, consistent with the discussion of the interface chip 306 above with reference to FIGS. 3A and 3B, the reduced number of signals that are routed through the interface chip 406 can enable fewer bond pads in a pad ring area of the interface chip 406 in comparison to the pad ring area of the interface chip 206 (FIG. 2B), which is expected to enable a reduced width of the pad ring area of the interface chip 406 and/or an increased aspect ratio of the interface chip 406 (e.g., a reduced width W10 in comparison to the width W4 of the interface chip 206 in FIG. 2B). The fewer bond pads and/or the reduced width of the pad ring area is expected to enable use of shorter RDL paths/RDL routing lengths, which (e.g., in combination with the fewer bond pads) is expected to reduce parasitic loading and/or pad capacitance in the interface chip 406 in comparison to the interface chip 206 of FIG. 2B. Furthermore, the fewer bond pads, the reduced width of the pad ring area, and/or the increased aspect ratio of the interface chip 406 is expected to enable use of larger bond fingers 407a (e.g., having widths W11 that are larger than the widths W5 of the bond fingers 207 in FIG. 2A), which may be useful to accommodate multiple connections (or tacks) on a given bond finger 407a. In these and other embodiments, the fewer bond pads, the reduced width of the pad ring area, and/or the increased aspect ratio (e.g., the reduced width W10) of the interface chip 406 can facilitate use of additional bond fingers 407b, which can enable use of additional power and/or ground wire bonds 409b extending between the substrate 401 and the interface chip 406 that is expected to improve power delivery and/or grounding performance to the interface chip 406 and/or to the semiconductor dies 403e-403h (e.g., by reducing the impedance of the power delivery network).

Moreover, the reduced width of the pad ring area of the interface chip 406 and/or the increased aspect ratio of the interface chip 406 are expected to enable optimizing an amount of spacing between the interface chip 406 and the first semiconductor die 403a of the stack 402. As a specific example, the interface chip 406 can be positioned a distance D4 away from an edge of the first semiconductor die 403a of the stack 402, which can be greater than the distance D2 that the interface chip 206 is positioned away from an edge of the first semiconductor die 202a in FIG. 2A. The larger distance D4 can also contribute to the increased spacing between the wire bonds 408a-408d, which can reduce the risk of crosstalk between the wire bonds 408a-408d.

Consistent with the description of the semiconductor device 300 above with reference to FIGS. 3A and 3B, various signals can be transmitted along the wire bonds 409a, 408a, 408b, 408c, and/or 408d of the semiconductor device 400 illustrated in FIG. 4A. These signals can include power (e.g., VDDQ, VDDQ2, VDD2, VCCP), ground (e.g., VSS), and/or control and/or timing signals (e.g., command/address (CA) signals, chip select (CS) signals, clock (CK) signals, etc.). In addition, although the semiconductor device 400 is illustrated in FIG. 4A with eight semiconductor dies arranged in a 2-2-2-2 stack configuration, the present technology is not so limited. In other embodiments of the present technology, semiconductor devices can include a different number of semiconductor dies (e.g., one, two, three, four, five, six, seven, or more than eight semiconductor dies) and/or can include semiconductor dies arranged in other stack configurations (e.g., 4-4 stacks, 1-1-1-1 stacks, 2-2 stacks, 4-high stacks, 8-high stacks, 16-high stacks, 32-high stacks, etc.) besides a 2-2-2-2 stack configuration.

The design of FIG. 4A can also include staggering the semiconductor dies 403 of the stack 402. In particular, in comparison to the subsets 212a-212d of the semiconductor dies 203 of FIG. 2A that are vertically aligned within one another in the stack 202, the subsets 412a-412d of the semiconductor dies 403 of FIG. 4A can be staggered (or at least partially laterally offset from one another) in the stack 402 such that the subsets 412a-412d are positioned generally along line 470 in FIG. 4A and are not fully vertically aligned with one another. This can reduce distances (a) between edges of the semiconductor dies 403a-403d and the bond fingers 407a and (b) between edges of the semiconductor dies 403e-403h and bond pads of the pad ring area of the interface chip 406, which are expected to further reduce the lengths of the wire bonds 408a-408d. In turn, use of the shorter wire bonds 408a-408d is expected to reduce manufacturing costs, shorten the associated signal paths, reduce an amount of observed voltage (IR) drop along power and/or ground wire bonds 408a-408d, improve performance, and/or improve signal integrity.

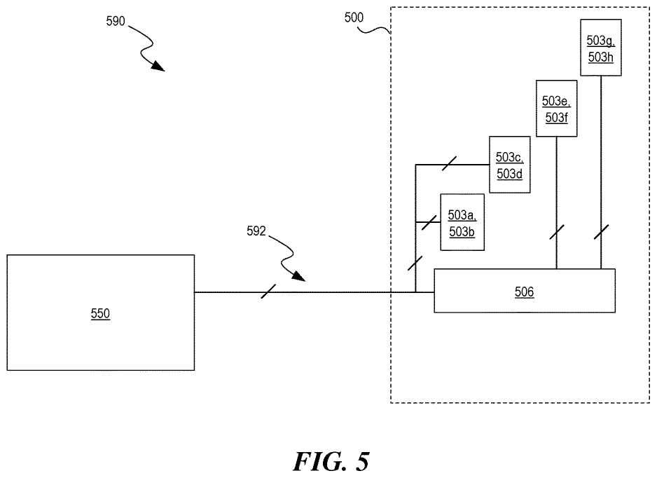

FIG. 5 illustrates a block diagram of a system 590 configured in accordance with various embodiments of the present technology. As shown, the system 590 includes a host device 550 and a semiconductor device 500. In some embodiments, the host device 550 can be a controller (e.g., a memory controller, a central processing unit, a graphics processing unit, a tensor processing unit, an application processor, etc.), a power supply, or another upstream system component. The semiconductor device 500 can be an example of the semiconductor device 300 described above with reference to FIGS. 3A and 3B, an example of the semiconductor device 400 described above with reference to FIGS. 4A and 4B, and/or an example of other semiconductor devices configured in accordance with various embodiments of the present technology. For example, the semiconductor device 500 can include a plurality of semiconductor dies 503 (identified individually in FIG. 5 as first through eighth semiconductor dies 503a-503h) and an interface chip 506. In other embodiments, the semiconductor device 500 can include another chip (e.g., a data buffer chip, a registered clock driver chip, a re-driver chip, a re-timer chip, a multiplexer integrated circuit chip, etc.) in addition to or in lieu of the interface chip 506.

As shown, the host device 550 is communicably coupled to each of the semiconductor dies 503a-503h and the interface chip 506 via a signal bus 592. For example, the host device 550 can be (e.g., directly) communicably coupled to the semiconductor dies 503a-503d via external contacts (not shown), a package substrate (not shown), and/or one or more bond fingers (not shown) of the semiconductor device 500. As another example, the host device 550 can be communicably coupled to the semiconductor dies 503e-503h via the interface chip 506 and/or the one or more external contacts (not shown), the package substrate (not shown), and/or one or more bond fingers (not shown). Thus, consistent with the description of FIGS. 3A-4B above, a subset of the signals transmitted over the signal bus 592 can be routed (e.g., directly) to the semiconductor dies 503a-503d without being routed through the interface chip, and another subset of the signals transmitted over the signal bus 592 can be routed to the semiconductor dies 503e-53h via the interface chip 506.

Various signals can be transmitted over the signal bus 592. For example, in some embodiments, power (e.g., VDDQ, VDDQ2, VDD2, VCCP) and/or ground (e.g., VSS) can be provided over one or more signal traces of the signal bus 592. In these and other embodiments, control and/or timing signals (e.g., command/address (CA) signals, chip select (CS) signals, clock (CK) signals, etc.) can be transmitted over one or more signal traces of the signal bus 592.

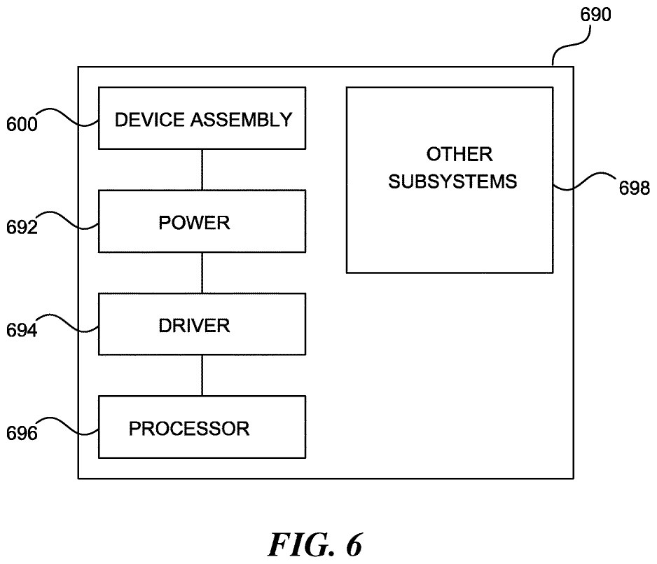

Any one of the semiconductor devices and semiconductor device assemblies described above with reference to FIGS. 1-5 can be incorporated into any of a myriad of larger and/or more complex systems, a representative example of which is system 690 shown schematically in FIG. 6. The system 690 can include a semiconductor device assembly 600 (e.g., similar to the semiconductor devices 300, 400, and/or 500 described above with reference to FIGS. 3A-5), a power source 692, a driver 694, a processor 696, and/or other subsystems or components 698. The semiconductor device assembly 600 can include features generally similar to those of the semiconductor devices described above with reference to FIGS. 3A-5. The resulting system 690 can perform any of a wide variety of functions, such as memory storage, data processing, and/or other suitable functions. Accordingly, representative systems 690 can include, without limitation, hand-held devices (e.g., mobile phones, tablets, digital readers, and digital audio players), computers, vehicles, appliances and other products. Components of the system 690 may be housed in a single unit or distributed over multiple, interconnected units (e.g., through a communications network). The components of the system 690 can also include remote devices and any of a wide variety of computer readable media.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A semiconductor device, comprising:
a substrate;
an interface chip disposed on the substrate;
a plurality of semiconductor dies disposed on the substrate;
a first plurality of wire bonds coupling a first subset of the plurality of semiconductor dies to the substrate apart from the interface chip; and
a second plurality of wire bonds coupling a second subset of the plurality of semiconductor dies to the substrate via the interface chip.

2. The semiconductor device of claim 1, wherein the interface chip is coupled to the substrate via a third plurality of wire bonds, and wherein the interface chip is configured to route signals received via one or more wires bonds of the third plurality to the second subset of the plurality of semiconductor dies via one or more wire bonds of the second plurality.

3. The semiconductor device of claim 2, wherein:
the substrate includes a plurality of bond fingers;
the first plurality of wires bonds couple corresponding ones of the plurality of bond fingers to the first subset of the plurality of semiconductor dies; and
the third plurality of wire bonds couple corresponding ones of the plurality of bond fingers to the interface chip.

4. The semiconductor device of claim 3, wherein the plurality of bond fingers are a first plurality of bond fingers, wherein the substrate further includes a second plurality of bond fingers positioned on a side of the interface chip opposite the first plurality of bond fingers, and wherein a fourth plurality of wire bonds couple corresponding ones of the second plurality of bond fingers to the interface chip.

5. The semiconductor device of claim 1, wherein the plurality of semiconductor dies are arranged in a 4-4 stack configuration on the substrate in which the second subset is positioned over the first subset.

6. The semiconductor device of claim 5, wherein the second subset is separated from the first subset via a spacer.

7. The semiconductor device of claim 1, wherein the plurality of semiconductor dies are arranged in a 2-2-2-2 stack configuration on the substrate in which a third subset of the plurality of semiconductor dies is positioned over the first subset, the second subset is positioned over the third subset, and a fourth subset of the plurality of semiconductor dies is positioned over the second subset.

8. The semiconductor device of claim 7, wherein:
the third subset is separated from the first subset via a first spacer;
the second subset is separated from the third subset via a second spacer; and
the fourth subset is separated from the second subset via a third spacer.

9. The semiconductor device of claim 7, further comprising:
a third plurality of wire bonds coupling the third subset of the plurality of semiconductor dies to the substrate apart from the interface chip; and
a fourth plurality of wire bonds coupling the fourth subset of the plurality of semiconductor dies to the substrate via the interface chip.

10. The semiconductor device of claim 7, wherein the first, second, third, and/or fourth subsets are staggered from one another in the 2-2-2-2 stack configuration such that the first, second, third, and/or fourth subsets are at least partially laterally offset from one another.

11. The semiconductor device of claim 1, wherein at least some of the first plurality of wire bonds and at least some of the second plurality of wire bonds are configured as power or ground wire bonds.

12. The semiconductor device of claim 1, wherein at least some of the first plurality of wire bonds and at least some of the second plurality of wire bonds are configured to transmit command/address signals, chip select signals, or clock signals.

13. The semiconductor device of claim 1, wherein the semiconductor device is a memory device, and wherein one or more of the plurality of semiconductor dies are memory dies.

14. The semiconductor device of claim 13, wherein the semiconductor device is a low-power dynamic random-access memory (LPDRAM) device.

15. A system, comprising:
a host device; and
a semiconductor device communicably coupled to the host device via a signal bus, the semiconductor device including:
a plurality of semiconductor dies; and
an interface chip,
wherein a first subset of the plurality of semiconductor dies is coupled to the host device via the interface chip, and
wherein a second subset of the plurality of semiconductor dies is coupled to the host device apart from the interface chip.

16. The system of claim 15, wherein:
the semiconductor device further includes a substrate;
the plurality of semiconductor dies and the interface chip are disposed on the substrate;
the first subset of the plurality of semiconductor dies is coupled to the substrate via a plurality of bond fingers and a first plurality of wire bonds; and
the second subset of the plurality of semiconductor dies is coupled to the substrate via a second plurality of wire bonds and the interface chip.

17. The system of claim 16, wherein the interface chip is coupled to the substrate via the plurality of bond fingers and a third plurality of wire bonds.

18. The system of claim 17, wherein the plurality of bond fingers is a first plurality of bond fingers, wherein the interface chip is further coupled to the substrate via a second plurality of bond fingers and a fourth plurality of wire bonds, and wherein the second plurality of bond fingers is positioned on an opposite side of the interface chip from the first plurality of bond fingers.

19. A semiconductor device, comprising:
a substrate;
a silicon chip disposed on the substrate; and
a stack of semiconductor dies disposed on the substrate at a second position that is laterally offset from the silicon chip,
wherein a first subset of the semiconductor dies is coupled to the substrate via a first plurality of wire bonds and apart from the silicon chip, and
wherein a second subset of the semiconductor dies is coupled to the substrate via a second plurality of wire bonds and the silicon chip.

20. The semiconductor device of claim 19, wherein the silicon chip includes an interface chip, a data buffer chip, a registered clock driver chip, a re-driver chip, a re-timer chip, or a multiplexer integrated circuit chip.
